(19) United States
(12) Patent Application Publication
(10) Pub. No.: US 2021/0273178 A1
(43) Pub. Date: Sep. 2, 2021

(54) DISPLAY DEVICE AND METHOD OF MANUFACTURING DISPLAY DEVICE

(71) Applicant: SHARP KABUSHIKI KAISHA, Sakai City, Osaka (JP)

(72) Inventors: MASANOBU MIZUSAKI, Sakai City, Osaka (JP); MASAKAZU SHIBASAKI, Sakai City, Osaka (JP)

(21) Appl. No.: 17/276,625

(22) PCT Filed: Sep. 28, 2018
(86) PCT No.: PCT/JP2018/036450

§ 371 Date: Mar. 16, 2021

(51) Int. Cl. H01L 51/00; H01L 27/32; H01L 51/50; H01L 51/56

(52) U.S. Cl. CPC H01L 51/0067; H01L 27/3244; H01L 51/0097; H01L 51/003; H01L 2251/5338; H01L 51/56; H01L 2227/323; H01L 2227/326; H01L 51/5016

(57) ABSTRACT

A display device is provided with a display region and a frame region surrounding the display region. The display region includes a light-emitting element layer that includes a plurality of light-emitting elements, a TFT layer provided below the light-emitting element layer to drive the light-emitting elements, and a sealing layer covering the light-emitting element layer. The light-emitting element layer is provided with a plurality of light-emitting layers, and each of the light-emitting layers contains a hindered amine compound and/or a derivative of a hindered amine compound.

### TECHNICAL FIELD

The present invention relates to a display device and a method of manufacturing the display device.

### BACKGROUND ART

A vapor deposition technique is a current mainstream method for forming organic light-emitting diodes (OLED), but this method requires the use of a fine metal mask to divide the OLED into the three colors of red (R), green (G), and blue (B). However, when a fine metal mask is used, a problem arises in which the fine metal mask itself warps. Furthermore, when a fine metal mask is used, the resolution of the display device does not increase, and even if an attempt is made to increase the resolution of the display device, a problem of color mixing of the OLEDs occurs. Therefore, as in PTL 1, a method for preparing OLEDs of the three colors of R, G, and B using a photoresist method and a fluorine-based solvent, without using a fine metal mask, is disclosed.

### CITATION LIST

### Patent Literature

PTL 1: WO2016/105473 A1 (International publication date: 30 Jun. 2016)

### SUMMARY OF INVENTION

### Technical Problem

However, a problem with the method disclosed in PTL 1 is that the service life of the OLED element is reduced due to organic material, such as a luminescent material contained in the light-emitting element layer, directly contacting various solvents (for example, fluorine-based solvents, release agents, and the like). This decrease in the service life is thought to be due to the promotion of oxidation of the organic material by oxygen contained in the solvent. When the organic material oxidizes, radicals formed by oxidation interact with luminescent bodies, which are in an excited state, and as a result, cause quenching of the luminescent bodies and reduce the service life of the OLED.

### Solution to Problem

To solve the above problem, a display device according to an aspect of the present application is provided with: a display region that includes a light-emitting element layer containing a plurality of light-emitting elements, a TFT layer provided below the light-emitting element layer and configured to drive the light-emitting elements, and a sealing layer covering the light-emitting element layer; and a frame region surrounding the display region, wherein the light-emitting element layer is provided with a plurality of light-emitting layers, and each of the light-emitting layers contains a hindered amine compound and/or a derivative of a hindered amine compound.

A method of manufacturing a display device according to an aspect of the present application is a method of manufacturing a display device by forming, on a substrate, a light-emitting element layer that is patterned, the method including the steps of: forming a mask pattern on the substrate using a photoresist; vapor depositing a light-emitting element material containing a hindered amine compound and/or a derivative of a hindered amine compound onto the substrate using an open mask; and removing the mask pattern from the substrate.

### Advantageous Effects of Invention

By introducing a hindered amine compound into the light-emitting layer without using a fine metal mask, quenching of a luminescent body caused by the conversion of an oxide into a radical can be suppressed. Therefore, it is possible to produce a display device provided with an OLED having a long service life.

### BRIEF DESCRIPTION OF DRAWINGS

FIG. 1 is a flowchart illustrating an example of a method of manufacturing a display device 1 provided with an OLED.

FIG. 2(a) is a cross-sectional view illustrating a configuration example during the formation of the display device 1 according to the present embodiment. FIG. 2(b) is a cross-sectional view illustrating a configuration example of the display device 1 according to the present embodiment.

FIG. 3 is a flowchart illustrating an example of a method of manufacturing the display device of the present embodiment.

FIG. 4 is a schematic view illustrating an example of a method of manufacturing a display device using a photoresist method.

FIG. 5(a) is a diagram illustrating a reaction that occurs until a radical is formed after a solvent substance such as a release agent has been oxidized. FIG. 5(b) is a diagram illustrating a cycle reaction of radical scavenging and radical release by a hindered amine compound.

FIG. 6 is a schematic view illustrating another example of a method of manufacturing a display device using a photoresist method.

FIG. 7 is a schematic view illustrating another example of a method of manufacturing a display device using a photoresist method.

### DESCRIPTION OF EMBODIMENTS

### Main Points of the Present Invention

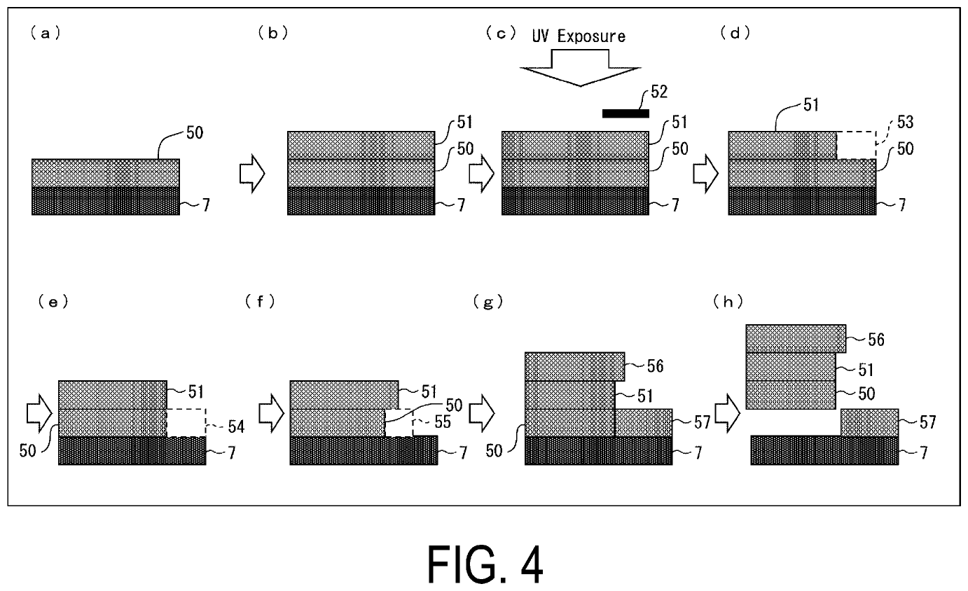

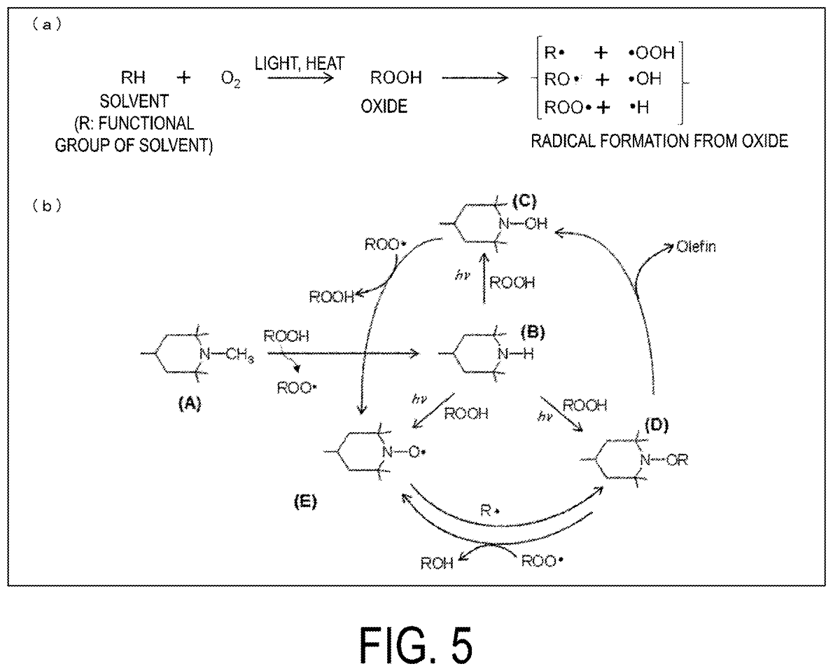

Hereinafter, the main points of the present invention will be described with reference to FIG. 4 and FIG. 5. FIG. 4 is a schematic view illustrating an example of a method of manufacturing a display device using a common photoresist method.

As illustrated in FIG. 4, a conventional photoresist method includes the following steps. A resist underlayer 50 is formed on a substrate 7 ((a) of FIG. 4, resist underlayer forming step), and a resist layer 51 is formed on an upper layer of the resist underlayer 50 ((b) of FIG. 4, resist layer forming step). Subsequently, light is irradiated through a photomask 52 in the direction of a resist layer 51 ((c) of FIG. 4, exposure step). Next, of the resist layer 51, an exposed region 53 exposed through the exposure step, and of the resist underlayer 50, a region 54 in contact with the exposed region 53 are removed from the substrate 7 by using a developing solution ((d) and (e) of FIG. 4), developing step). Furthermore, similar to the matter described above, a region 55 adjacent to the region 54 is removed by a developing solution ((f) of FIG. 4, developing step). Next, a light-emitting element layer 56 is vapor deposited onto the resist layer 51, and a first light-emitting element layer 57 is vapor deposited onto the substrate 7 ((g) of FIG. 4, vapor depositing step). After the vapor depositing step, the resist underlayer 50, and the resist layer 51 and light-emitting element layer 56 deposited on the resist underlayer 50 are peeled from the substrate 7 using a release agent. As a result, only the first light-emitting element layer 57 is formed on the substrate 7 ((h) of FIG. 4, peeling step).

In (h) of FIG. 4, a release agent (not illustrated) is used to peel the resist underlayer 50 from the substrate 7, and thereby the resist underlayer 50 is peeled from the substrate 7. At this time, the release agent contacts the first light-emitting element layer 57 formed after the vapor deposition. Oxygen is contained in the solvent of the release agent. Therefore, when the release agent contacts an organic material forming the first light-emitting element layer 57 or the like, the oxygen in the release agent penetrates into the organic material and interacts with a luminescent body, which is in an excited state. Through this, quenching of the luminescent body is promoted, and as a result, a reduction in the service life of the light-emitting element is accelerated.

In light of the above problems, the present inventors introduced a radical scavenger into the light-emitting layer included in the light-emitting element layer in order to suppress the reduction in the service life of the light-emitting element. A hindered amine compound was used as the radical scavenger.

The principle behind the scavenging of radicals by the hindered amine compound is described here with reference to FIG. 5. (a) of FIG. 5 is a diagram illustrating a reaction that occurs until a radical is formed after a solvent substance such as a release agent has been oxidized. In addition, (b) of FIG. 5 is a diagram illustrating a cycle reaction of radical scavenging and radical release by the hindered amine compound.

The hindered amine compounds indicated by (A) to (D) in FIG. 5 scavenge and a radicalized substance and react therewith, and thereby the cycle reaction illustrated in (b) of FIG. 5 is carried out. The present inventors used hindered amine compounds like those indicated by (A) to (D) in FIG. 5 and a nitroxy radical-type hindered amine like that indicated by (E) as radical scavengers by introducing the materials thereof into the light-emitting layer. As a result, the present inventors discovered that when a hindered amine compound like that indicated by (A) to (D) in FIG. 5 is introduced into the light-emitting layer, the radical scavenging efficiency is increased, and an effect of suppressing quenching with respect to the light-emitting element is improved. In addition, the present inventors also discovered that in comparison to the introduction of a hindered amine compound like that indicated by (A) to (D) in FIG. 5 into the light-emitting layer, when a nitroxy radical-type hindered amine is introduced into the light-emitting layer, the radical scavenging efficiency is further increased, and the effect of suppressing quenching with respect to the light-emitting element is further improved. It is assumed that this occurs because in the case in which a nitroxy radical-type hindered amine is included in the light-emitting layer, the nitroxy radical-type hindered amine can directly scavenge radicals without requiring a reaction process for radicalizing the hindered amine compound itself, which differs from the case in which hindered amine compounds like those indicated by (A) to (D) in FIG. 5 are included in the light-emitting layer.

Hereinafter, a configuration of a display device that includes the light-emitting layer described above, and a method for manufacturing the display device thereof are described.

### Display Device Configuration

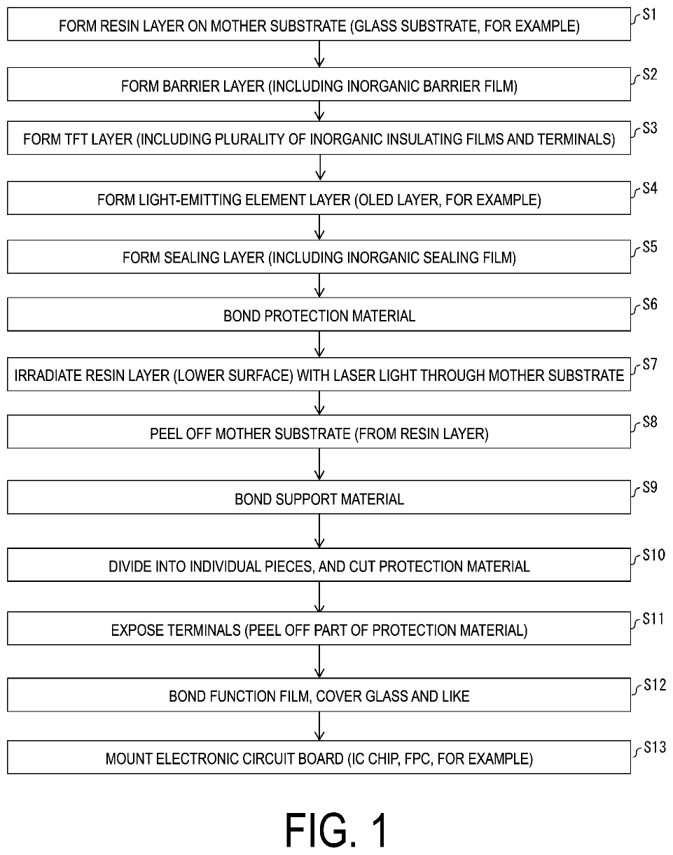

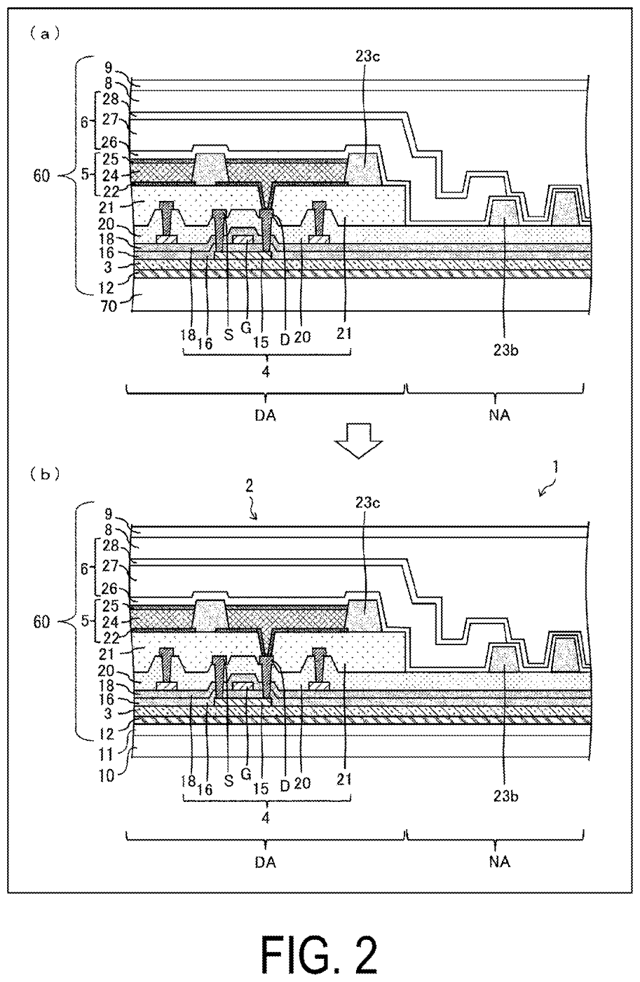

A display device 1 of the present invention is described with reference to FIGS. 1 and 2. The configuration and the like of a display device 1 provided with an organic light-emitting diode (OLED) as a light-emitting element is described below as an example of the display device 1.

FIG. 1 is a flowchart illustrating an example of a method of manufacturing the display device 1 provided with an OLED. FIG. 2(a) is a cross-sectional view illustrating a configuration example during the formation of the display device 1 according to the present embodiment. FIG. 2(b) is a cross-sectional view illustrating a configuration example of the display device 1 according to the present embodiment.

When a flexible display device 1 is to be manufactured, as illustrated in FIGS. 1 and 2, the following steps S1 to S13 are generally implemented.

Step S1: A resin layer 12 is formed on a transparent mother substrate 70 such as a glass substrate.

Step S2: An inorganic barrier film 3 is formed.

Step S3: A TFT layer 4 including a plurality of inorganic insulating films 16, 18, and 20 and a flattening film 21 is formed.

Step S4: A light-emitting element layer 5 such as an OLED element layer is formed.

Step S5: A sealing layer 6 including inorganic sealing films 26 and 28 and an organic sealing film 27 is formed.

Step S6: A protection material 9 such as a PET film is bonded on the sealing layer 6 via an adhesive layer 8.

Step S7: The resin layer 12 is irradiated with laser light. Here, the resin layer 12 absorbs the irradiated laser light, and thus a lower face of the resin layer 12, which is an interface with the mother substrate 70, is altered due to ablation. Through this, a peeling layer is formed, and a bonding force between the resin layer 12 and the mother substrate 70 decreases.

Step S8: The mother substrate 70 is peeled from the resin layer 12. This causes a layered body 60 to be peeled from the mother substrate 70. Here, the layered body 60 indicates the entire multilayered body formed on the mother substrate 70, and in the example illustrated in FIG. 2(a), the layered body 60 indicates layers from the resin layer 12 formed on the mother substrate 70 to the protection material 9, which is the uppermost layer.

Step S9: A support material 10 such as a PET film is bonded to the lower face of the resin layer 12 via an adhesive layer 11.

Step S10: The mother substrate 70 is divided, and the protection material 9 is cut to thereby cut out a plurality of display elements.

Step S11: The protection material 9 on a terminal portion of the TFT layer 4, which drives the light-emitting elements, is peeled off to expose a terminal.

Step S12: A function film (not illustrated) is bonded.

Step S13: An electronic circuit board is mounted on the terminal portion using an ACF or the like.

Through the above steps, the display device 1 provided with an OLED is formed as one example of a flexible display.

Note that in FIGS. 2(a) and 2(b), 4 denotes a TFT layer, 15 denotes a semiconductor film, 16 denotes a gate insulating film, 22 denotes an anode electrode, 23b denotes a bank, 23c denotes a partition, 24 denotes an EL layer, 25 denotes a cathode electrode, 26 denotes a first inorganic sealing film, 27 denotes an organic sealing film, 28 denotes a second inorganic sealing film, G denotes a gate electrode, S denotes a source electrode, D denotes a drain electrode, DA denotes an active region, and NA denotes a non-active region.

The active region DA corresponds to a region where the light-emitting element layer 5 is formed (a region where the semiconductor film 15, the gate electrode G, the source electrode S, and the drain electrode D are formed) and can be represented as a display region. In contrast, the non-active region NA is the region other than the active region DA, is a frame region surrounding the display region, and is a region where terminals used for connection with an electronic circuit board and the like are formed. In addition to the constituent elements described above, the display device 1 is configured by adding other necessary constituent elements such as a housing and a control and power supply system.

The EL layer 24 includes a hole injecting layer, a hole transport layer, an electron transport layer, an electron injection layer (not illustrated), an electron blocking layer, a hole blocking layer, and a plurality of light-emitting layers. Note that the layers other than the light-emitting layers are not essential to the EL layer 24, and may be formed, as appropriate, in accordance with the properties that are required of the EL element 24.

Each light-emitting layer is a light-emitting unit including a plurality of light-emitting elements. The light-emitting layer includes a first light-emitting layer, a second light-emitting layer, and a third light-emitting layer.

### Materials Included in the Light-Emitting Layer

Materials included in the light-emitting layer are described in detail below. The first light-emitting layer, the second light-emitting layer, and the third light-emitting layer may be each formed from a host material and a luminescent material, that is, a dopant material exhibiting fluorescence (luminescent dopant and guest material), or may be formed from the dopant material alone. The host material is a compound in which holes and electrons can be injected, and has a function of allowing a luminescent dopant to emit light by holes and electrons that are transported and recombine with each other within a molecule thereof. In the case where a host material is used, the host material to be used is an organic compound having a higher Silevel and/or a higher energy level in the minimum excited triplet state (hereinafter referred to as the“Tilevel”) than that of the luminescent material. Thus, the host material can trap the energy of the luminescent material within the luminescent material, and thus can enhance the luminous efficiency by the luminescent material.

The host material is appropriately selected based on the color of the light-emitting element, and examples thereof include a hole-transporting material and an electron-transporting material.

When the light-emitting layer is a green light-emitting layer, the light-emitting layer is preferably formed from a host material and a dopant material from the perspective of light-emitting quantum efficiency and element service life. Furthermore, as examples of the host material, a P-type host material and an N-type host material are preferably used. According to the above-described configuration, the balance between the light-emitting quantum efficiency and the element service life can be adjusted.

Examples of the P-type host material include 4,4′-bis(9H-carbazol-9-yl)biphenyl and the like.

Examples of the N-type host material include tris(8-quinolinolato)aluminum and the like.

The dopant material may be, for example, a phosphorescent luminescent material or a fluorescent luminescent material. Examples thereof include (2,2′-bipyridine)bis (2-phenylpyridinato)iridium (III) hexafluorophosphate and tris(8-quinolinolato) aluminum.

When the light-emitting layer is a red light-emitting layer, the luminescent material is not particularly limited. Examples of dopant materials include, for example, tris [1-phenylisoquinoline-C²,N]iridium, and the like. From the perspective of shortening the manufacturing process by reducing the total number of materials, the P-type host material and/or the N-type host material included in the green light-emitting layer is preferably included in the light-emitting layer as a luminescent material.

When the light-emitting layer is a blue light-emitting layer, an anthracene-based compound or derivative of an anthracene-based compound is preferably used as the host material from the perspectives of improving chromaticity, light-emitting quantum efficiency, and element service life.

The anthracene-based compound or derivative of an anthracene-based compound is not particularly limited, and may be appropriately selected according to the configuration and required properties of the light-emitting element to be used.

Examples of the derivative of an anthracene-based compound include a substance having the following structural formula.

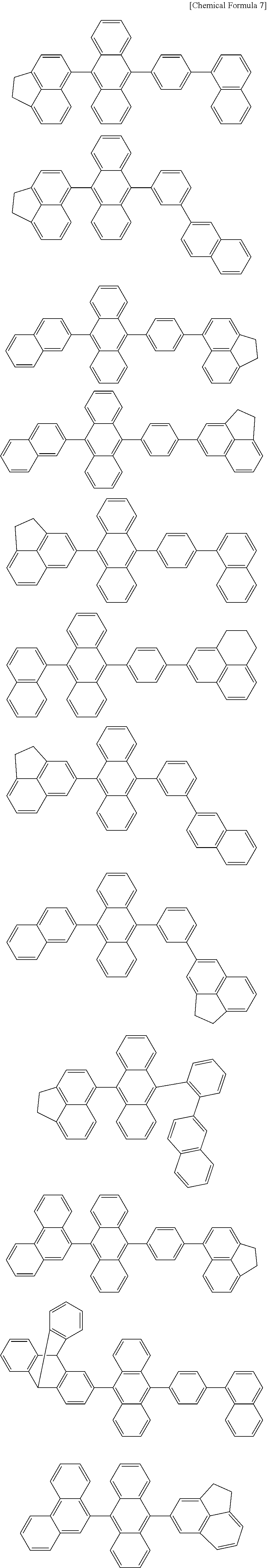

In addition to the aforementioned components, each of the light-emitting layers includes a hindered amine compound and/or a derivative of a hindered amine compound derivative. Herein, “hindered amine compound” refers to, for example, a compound having a structure represented by general formula 1 below.

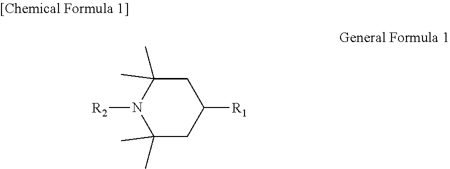

Here, R₁ is any organic group, and R₂ is H or any organic group. Examples of compounds having a structure represented by general formula 1 described above include, for example, the compounds having the following structural formulas.

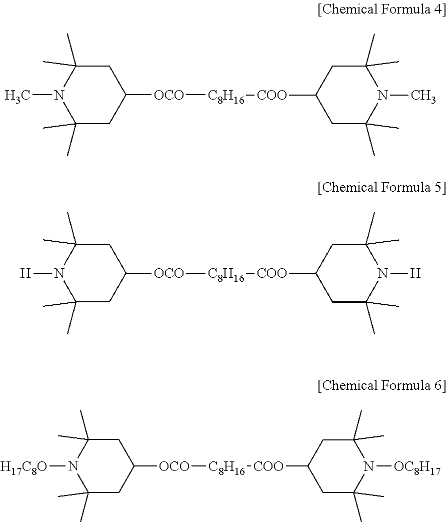

A display device provided with an OLED having a long service life can be realized by including a compound of a structural formula described above in each light-emitting layer.

The mixing ratio (introduction amount) of the hindered amine compound contained in the light-emitting layer with respect to the total organic material is, in terms of weight percentage, preferably from 0.01 wt. % to 0.1 wt. %, and more preferably from 0.03 wt. % to 0.07 wt. %.

When the introduction amount of the hindered amine compound is too low, the extent of improvement in the service life decreases due to a reduction in the efficiency of scavenging enzyme radicals. Furthermore, if the introduction amount of the hindered amine compound is too high, the hindered amine itself seeps out from the light-emitting layer to the hole transport layer or the electron transport layer, and scavenges carriers, and therefore the luminous efficiency is reduced.

Here, the efficiency (EQE) of the light-emitting element depends primarily on the exciton generation efficiency according to a recombination of holes and electrons. On the other hand, the service life is dependent on chemical structural changes of the material. Since these two phenomena occur independently from each other, a reduction in EQE is not problematic with respect to extending the service life of the light-emitting element.

Also, in the present specification, the term “derivative” means a group of compounds that are produced by substituting a part of a molecule of a specific compound with another functional group or other atom. For example, from the perspective of increasing the efficiency of radical scavenging, the derivative of the hindered amine compound is preferably a nitroxy radical-type hindered amine.

Here, in the present specification, the term “nitroxy radical-type hindered amine” includes, for example, compounds having a structure represented by general formula 2 below.

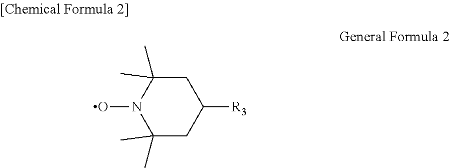

Here, R₃ is any organic group.

Examples of the nitroxy radical-type hindered amine include, for example, substances having the following structural formula.

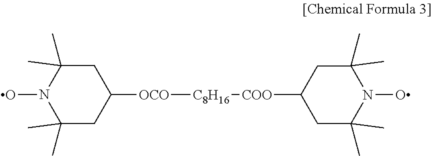

The mixing ratio (introduction amount) of the nitroxy radical-type hindered amine with respect to the total organic material contained in the light-emitting layer is, in terms of a weight percentage, preferably from 0.0003 wt. % to 0.01 wt. %, and more preferably from 0.001 wt. % to 0.007 wt. %. If the amount of nitroxy radical-type hindered amine introduced into the light-emitting layer is less than 0.0003 wt. %, the efficiency of scavenging enzyme radicals by the nitroxy radical-type hindered amine is reduced. As a result, the effect of suppressing a reduction in the service life of the light-emitting element is lower compared to a case where the introduction amount of the substance is equal to or greater than 0.0003 wt. %. On the other hand, when the amount of nitroxy radical-type hindered amine introduced into the light-emitting layer is equal to or greater than 0.01 wt. %, a portion of the organic material containing the nitroxy radical-type hindered amine may ooze out from the light-emitting layer and penetrate the carrier transport layer (or the carrier blocking layer) such as the hole transport layer or the electron transport layer. When the organic material penetrates the carrier transport layer, the holes (radical cations) or electrons (radical anions) flowing therein are scavenged by some of the substances contained in the organic material, the substances thereof including the nitroxy radical-type hindered amine. As a result, the efficiency of the OLED (specifically, the external quantum efficiency, and the like) is reduced.

Therefore, from the perspective of improving the efficiency of the OLED and exhibiting an effect of suppressing a reduction in service life, the introduction amount of the nitroxy radical-type hindered amine contained in the light-emitting layer with respect to the total organic material is preferably a content amount that is within the range described above.

Furthermore, as described below, the content amounts of the hindered amine compound and derivative of the hindered amine compound included in the first light-emitting layer, the second light-emitting layer, and the third light-emitting layer are preferably different for each of the light-emitting layers.

Note that various types of organic materials other than the materials described above may be included in the light-emitting layers.

### Method of Manufacturing a Light-Emitting Layer

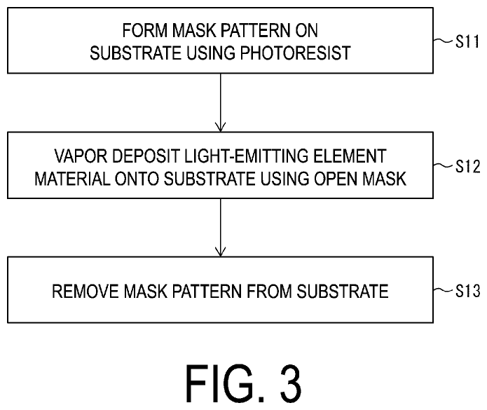

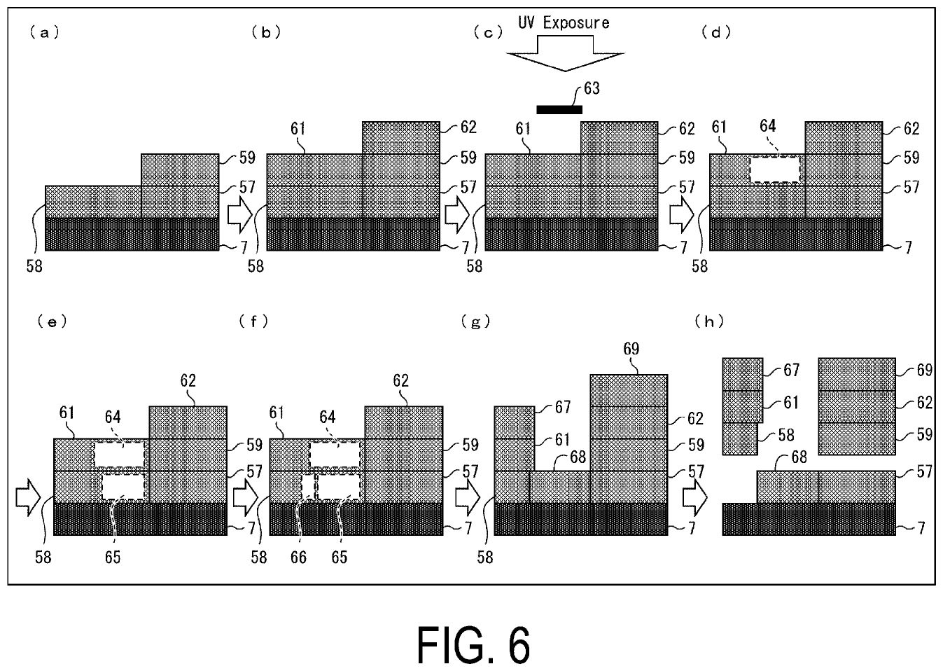

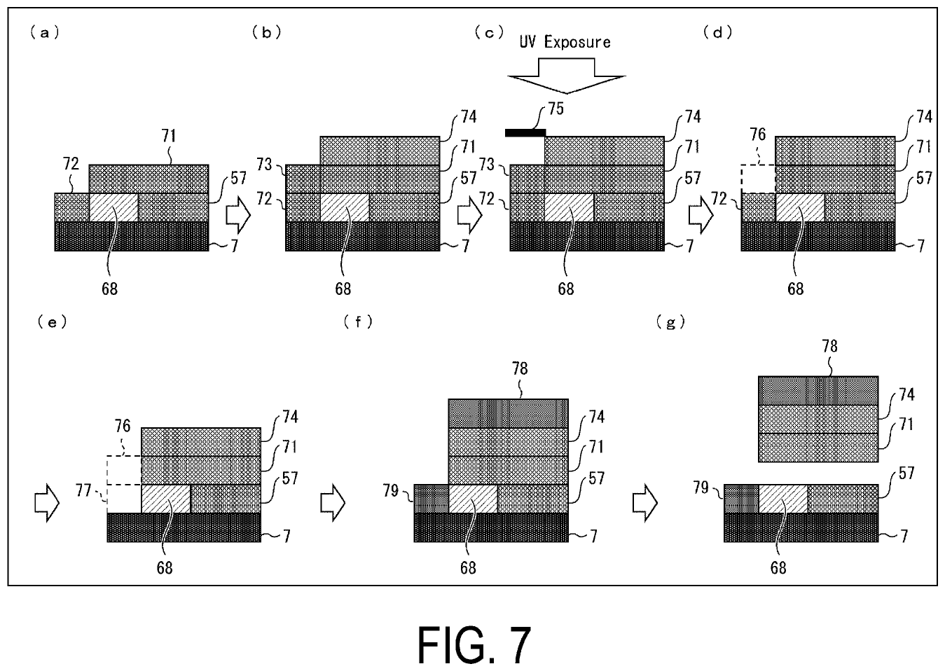

The steps that are implemented until each light-emitting layer described above is formed on the substrate are briefly described below with reference to FIG. 3, FIG. 6 and FIG. 7. Note that, with regard to each of the steps described below, a description is omitted for those steps described in FIG. 4 above in the Main Points of the Present Invention section.

FIG. 3 is a flowchart illustrating an example of a method of manufacturing the display device of the present embodiment. As illustrated in FIG. 3, a method for manufacturing a display device according to the present embodiment includes: (i) a step (S11) of forming a mask pattern on a substrate using a photoresist; (ii) a step (S12) of vapor depositing a light-emitting element material including a hindered amine compound and/or a derivative of a hindered amine compound onto the substrate using an open mask, and (iii) a step (S13) of removing the mask pattern from the substrate. By repeating the above-described steps (i) to (iii) three times, for example, a first light-emitting element layer 57 that includes the first light-emitting layer containing a blue light-emitting element, a second light-emitting element layer 68 that includes the second light-emitting layer containing a green light-emitting element, and a third light-emitting element layer 79 that includes the third light-emitting layer containing a red light-emitting element are each formed on the substrate.

The matter of “repeating the above-described steps (i) to (iii) three times” is described specifically below. First, the first light-emitting element layer 57 is formed on the substrate 7 by passing through each of the steps (a) to (h) illustrated in FIG. 4. Next, the second light-emitting element layer 68 is formed by passing through the same steps as those of the method for manufacturing the first light-emitting element layer 57. In other words, the second light-emitting element layer 68 is formed by passing through the following steps. Resist underlayers 58 and 59 are formed on the substrate 7 and on the first light-emitting element layer 57 ((a) of FIG. 6), and resist layers 61 and 62 are formed on the resist underlayers 58 and 59 ((b) of FIG. 6). Subsequently, light is irradiated through a photomask 63 onto the resist layer 61 ((c) of FIG. 6). Next, of the resist layer 61, an exposed region 64 that has been exposed, and of the resist underlayer 58, a region 65 in contact with the exposed region 64 are removed from the substrate 7 using a developing solution ((d) and (e) of FIG. 6). Furthermore, as described above, a region 66 adjacent to the region 65 is removed using the developing solution ((f) of FIG. 6). Here, the steps from (a) to (f) of FIG. 6 correspond to the step of S11. Next, light-emitting element layers 67 and 69 are newly vapor deposited onto the resist layers 61 and 62, and a second light-emitting element layer 68 is vapor deposited onto the substrate 7 ((g) of FIG. 6). Here, the step of (g) of FIG. 6 corresponds to the step of S12. After vapor deposition, the resist layers 61 and 62 vapor deposited onto the resist underlayers 58 and 59, and the resist underlayers 58 and 59 on which the light-emitting element layers 67 and 69 are layered are peeled from the substrate 7 or the first light-emitting element layer 57 using a release agent. As a result, the second light-emitting element layer 68 is formed on the substrate 7 adjacent to the first light-emitting element layer 57 ((h) of FIG. 6). Here, the step of (h) of FIG. 6 corresponds to S13.

After the formation of the second light-emitting element layer 68, the third light-emitting element layer 79 is formed by passing through the same steps as described above. In other words, the third light-emitting element layer 79 is formed by passing through the following steps. Resist underlayers 71 and 72 are formed on the substrate 7, the first light-emitting element layer 57, and the second light-emitting element layer 68 ((a) of FIG. 7), and resist layers 73 and 74 are further formed on the resist underlayers 71 and 72 ((b) of FIG. 7). Subsequently, light is irradiated through a photomask 75 onto resist layer 73 ((c) of FIG. 7). Next, an exposed region 76 in the exposed resist layer 73 and a region 77 (resist underlayer 72) in contact with the exposed region 76 are removed from the substrate 7 using a developing solution ((d) and (e) of FIG. 7). Here, the steps from (a) to (e) of FIG. 7 correspond to the step of S11. Next, a light-emitting element layer 78 is newly vapor deposited onto the resist layer 74, and a third light-emitting element layer 79 is vapor deposited onto the substrate 7 ((f) of FIG. 7). Here, the step of (f) of FIG. 7 corresponds to the step of S12. After vapor deposition, the resist layer 74 vapor deposited onto the resist underlayer 71, and the resist underlayer 71 on which the light-emitting element layer 78 was layered are peeled from the first light-emitting element layer 57 and the second light-emitting element layer 68 using a release agent. As a result, the third light-emitting element layer 79 is formed on the substrate 7 adjacent to the second light-emitting element layer 68 ((g) of FIG. 7). Here, the step of (g) of FIG. 7 corresponds to S13.

As described above, according to the present embodiment, the display device 1 can be manufactured without using a fine metal mask (FMM). Thus, in the present embodiment, the occurrence of problems such as “curvature” and “warping” can be prevented when a fine metal mask is used. Accordingly, in the present embodiment, the occurrence of color mixing or the like due to the shifting of the vapor deposition location at the substrate side during vapor deposition of the organic material can be prevented, and a high-resolution display device 1 can be easily manufactured.

The resist underlayer formed in the resist underlayer forming step described above is used to peel each layer formed after the resist underlayer forming step from the substrate in the peeling step.

The method for forming the resist underlayer is not particularly limited. Furthermore, the material included in the resist underlayer is not particularly limited.

The method of forming the photoresist layer is not particularly limited. A known material is used as the material included in the photoresist layer.

The exposure device used in the exposure step is not particularly limited. In addition, the light emitted from a light source provided in the exposure device is not particularly limited, but from the perspective of forming a more accurate mask pattern, the wavelength of the light thereof is preferably from 300 nm to 430 nm. Further, in the exposure step, a configuration for forming a more accurate mask pattern (for example, a light absorber or the like) may be used.

The components of the developing solution and the developing conditions used in the developing step are not particularly limited.

In the method for manufacturing a display device according to the present embodiment, if for example, the first light-emitting layer is formed in the above-described step (ii) performed a first time, the second light-emitting layer is formed in the above-described step (ii) performed a second time, and the third light-emitting layer is formed in the above-described step (ii) performed a third time, the content amount of the nitroxy radical-type hindered amine contained in each light-emitting layer is controlled to decrease in the order of the first light-emitting layer, the second light-emitting layer, and the third light-emitting layer.

By forming each light-emitting layer such that the content amount of the nitroxy radical-type hindered amine decreases in the order of the first light-emitting layer, the second light-emitting layer, and the third light-emitting layer, a high radical scavenging effect by the nitroxy radical-type hindered amine contained in the light-emitting layers can be maintained even if, after the formation of the third light-emitting layer, the first light-emitting layer and the second light-emitting layer contact a release agent or the like a plurality of times.

The vapor deposition method used in step (ii) described above is not particularly limited as long as the method controls the content amounts of the first light-emitting layer, the second light-emitting layer, and the third light-emitting layer so as to be different, and for example, a known technique such as a chemical vapor deposition (CVD) method may be used. Furthermore, the vapor deposition apparatus used in step (ii) described above is not particularly limited, and a vapor deposition apparatus provided with a general configuration may be used. In other words, a known vapor deposition method and a known vapor deposition apparatus can be used as long as the conditions of the vapor deposition method and the configuration of the vapor deposition apparatus are appropriately changed such that the content amount of the nitroxy radical-type hindered amine differs in each of the first light-emitting layer, the second light-emitting layer, and the third light-emitting layer obtained after implementing the above-described steps (i) to (iii) three times.

Examples of the vapor deposition method for controlling the content amount of nitroxy radical-type hindered amine in each of the light-emitting layers include, for example, a method of adjusting the concentration of the nitroxy radical-type hindered amine contained in various vapor deposition materials accommodated in a vapor deposition source of the vapor deposition apparatus.

The method for measuring the content amounts of the nitroxy radical-type hindered amine contained in the first light-emitting layer, the second light-emitting layer, and the third light-emitting layer obtained after repeating the above-described steps (i) to (iii) is not particularly limited, and examples thereof include mass spectrometry, 1H- and 13C-nuclear magnetic resonance (NMR), electron spin resonance (ESR), and Fourier-transform infrared spectroscopy (FTIR).

Moreover, the technique for measuring the service life of the light-emitting layer included in each of the light-emitting layers obtained after the above-described steps (i) to (iii) is not particularly limited, and examples thereof include a method of tracking the light emission luminance over time.

The vapor deposition material accommodated in the vapor deposition source includes the material of the above-described light-emitting layer, the material thereof being used to form the light-emitting layer (specifically, an organic material such as a hindered amine compound or a luminescent material). The vapor deposition material may be vapor deposited on the substrate from individual vapor deposition sources (such as crucibles) stored for each type of material. Alternatively, all of the above-described luminescent materials may be included in one vapor deposition source and formed on the substrate by co-evaporation from the vapor deposition source.

The method for removing the mask pattern from the substrate in the aforementioned step (iii) is not particularly limited.

Note that in the present embodiment, the method for manufacturing a display device was described using, as an example, a case in which the first light-emitting layer that includes the blue light-emitting element is formed in the steps (i) to (iii) performed the first time, the second light-emitting layer that includes the green light-emitting element is formed in the steps (i) to (iii) performed the second time, and the third light-emitting layer that includes the red light-emitting element is formed in the steps (i) to (iii) performed a third time, in that order, but the order in which the light-emitting elements of each color are formed is not particularly limited. However, material degradation is easily promoted when ultraviolet exposure onto long-wavelength luminescent materials increases. Thus, from the perspective of the problem thereof, it is preferable to form the first light-emitting layer that includes the blue light-emitting element, the second light-emitting layer that includes the green light-emitting element, and the third light-emitting layer that includes the red light-emitting element, in that order.

### EXAMPLES

### Example 1

An OLED element was prepared based on the above-described method for manufacturing a display device. After forming a resist underlayer on a substrate having an ITO electrode, and forming a resist layer on an upper layer of the resist layer thereof, the resist underlayer and the resist layer were peeled from the substrate only at locations where blue OLED elements are formed by photolithography. Note that in the exposure step, the amount of UV irradiation was 80 mJ/cm². Next, a blue OLED element was formed by vapor deposition. Note that the blue OLED element was configured including, on the ITO electrode, a hole injection layer, a hole transport layer, an electron blocking layer, a light-emitting layer (specifically including a derivative of an anthracene-based compound having the following structural formula), a hole blocking layer, an electron transport layer, an electron injection layer, and a cathode electrode. After the OLED element was fabricated, the region at which the resist underlayer and the resist layer were formed was completely peeled from the substrate using a stripper.

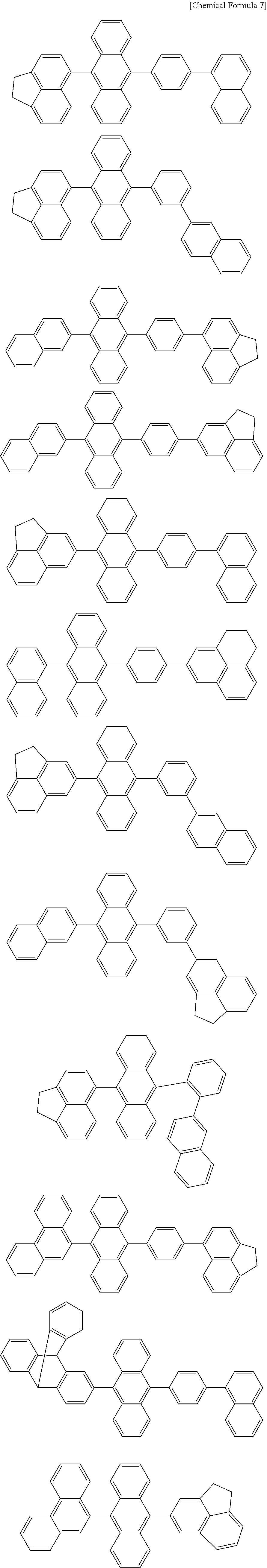

Here, OLED elements having various light-emitting layers containing a nitroxy radical-type hindered amine represented by the following structural formula were prepared with the content amount of the nitroxy radical-type hindered amine in terms of a weight percentage in each light-emitting layer being 0 (Comparative Example 1), 0.0003 wt. %, 0.001 wt. %, 0.01 wt. % and 0.1 wt. % relative to the total organic material contained in the light-emitting layer.

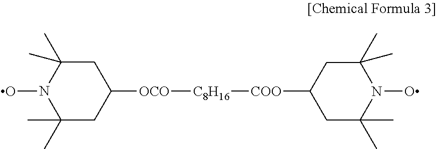

The service life of the blue OLED element included in each light-emitting layer was measured at a current drive condition of 10 mA/cm² (in a 25° C. environment). Additionally, the external quantum efficiency (EQE) of the blue OLED element was measured by the electric field light-emission characteristics (current voltage luminance characteristics evaluation). Furthermore, the service life and external quantum efficiency (EQE) were also evaluated for a blue OLED element prepared as a Comparative Example 2 without using a stripper (specifically, without immersing (dipping) the substrate on which the blue OLED element was formed, into a stripper). The results of the present example are shown in Table 1.

TABLE 1

| | Lifetime (Time to reach 90% in | |
|---|---|---|
| Introduction (wt. %) | relation to initial luminance) (h) | EQE (%) |
| 0 (Comparative Example 1) | 35 | 11.0 |
| 0.0003 (Example 1) | 55 | 11.3 |
| 0.001 (Example 2) | 58 | 11.3 |
| 0.01 (Example 3) | 58 | 10.9 |
| 0.1 (Example 4) | 58 | 10.2 |
| 0 (Comparative Example 2) | 58 | 10.7 |
| Not dipped into the stripper | | |

Table 1 shows results obtained by measuring the service life and external quantum efficiency of the blue OLED elements prepared in the present example. Here, “Lifetime” (the service life) refers to the “time (h) to reach 90% in relation to the initial luminance”.

The service life of the blue OLED element was increased when a nitroxy radical-type hindered amine was introduced into the light-emitting layer at the content amounts indicated in Table 1 for Examples 1 to 4. It was confirmed that this service life was the same as the service life of the blue OLED element (Comparative Example 2) prepared without using a stripper. It is speculated that the service life was the same because quenching of light emission due to the progression of oxidation was suppressed by the nitroxy radical-type hindered amine. In addition, nitroxy radicals are stable radicals that react only with oxygen radicals, and do not react with other organic substances. As a result, an effect of deactivating the oxygen radicals and extending the service life without reducing the external quantum efficiency (EQE) was obtained.

### Example 2

A blue OLED element layer was prepared by the same method as described above with the exception that a hindered amine compound represented by the following structural formula was introduced into the light-emitting layer.

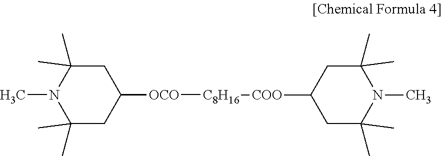

Blue OLED element layers were formed such that the content amount of the hindered amine compound contained in each blue OLED element layer was 0 (Comparative Example 3), 0.001 wt. %, 0.01 wt. %, 0.05 wt. % and 0.1 wt. %. The service life and external quantum efficiency (EQE) of the blue OLED elements were verified using the same method as described above. The results are shown in Table 2.

TABLE 2

| | Lifetime (Time to reach 90% in | |
|---|---|---|
| Introduction (wt. %) | relation to initial luminance) (h) | EQE (%) |
| 0 (Comparative Example 3) | 35 | 11.0 |
| 0.001 (Example 5) | 45 | 11.2 |
| 0.01 (Example 6) | 58 | 10.9 |
| 0.05 (Example 7) | 56 | 10.4 |
| 0.1 (Example 8) | 57 | 8.7 |
| 0 (Comparative Example 4) | 58 | 10.7 |
| Not dipped into the stripper | | |

Table 2 shows results obtained by measuring the service life and external quantum efficiency of the blue OLED elements prepared in the present example. As shown in Table 2, it was confirmed that the service life of the blue OLED element was increased by introducing a hindered amine compound into the light-emitting layer. In order to increase the service life of the blue OLED element to the same extent as in Comparative Example 4, it was necessary to set the amount of the hindered amine compound introduced into the light-emitting layer to 0.01 wt. % or higher (refer to Examples 5 to 8). It is thought that the reason for this is that when a hindered amine compound that was not a radical type was included in the light-emitting layer to scavenge oxygen radicals, a step of converting the hindered amine compound into a nitroxy radical through the cycle reaction illustrated in (b) of FIG. 5 became necessary, and thus it was necessary to increase the amount of the hindered amine compound added to the light-emitting layer by that amount.

However, it was confirmed that, as described in Example 5, even when the hindered amine compound was included in the light-emitting layer at a content amount of 0.001 wt. %, the service life of the light-emitting element was longer than the lifetime of Comparative Example 1.

Note that the EQE values of Examples 6, 7 and 8 were reduced compared to the EQE of Comparative Example 3. For the reasons described above, there is no problem with the effect of increasing the service life of the light-emitting element.

### Example 3

A blue OLED element layer was prepared by the same method as described above with the exception that a hindered amine compound represented by the following structural formula was introduced into the light-emitting layer.

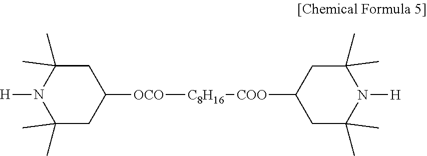

Blue OLED element layers were prepared with a content amount of the hindered amine compound in each blue OLED element layer being set to 0 (Comparative Example 5), 0.001 wt. %, 0.01 wt. %, and 0.1 wt. %, respectively. Furthermore, the service life and external quantum efficiency (EQE) of the blue OLED elements were verified using the same method as described above. The results of the present example are shown in Table 3.

TABLE 3

| | Lifetime (Time to reach 90% in | |
|---|---|---|
| Introduction (wt. %) | relation to initial luminance) (h) | EQE (%) |
| 0 (Comparative Example 5) | 35 | 11.0 |
| 0.001 (Example 9) | 48 | 11.1 |
| 0.01 (Example 10) | 57 | 10.6 |
| 0.1 (Example 11) | 55 | 8.3 |
| 0 (Comparative Example 6) | 58 | 10.7 |
| Not dipped into the stripper | | |

Table 3 shows results obtained by measuring the service life and external quantum efficiency of the blue OLED elements prepared in the present example. As shown in Table 3, as in Example 2 described above, it was confirmed that the service life of the blue OLED element was increased by introducing a hindered amine compound into the light-emitting layer. In order to increase the service life of the blue OLED element to the same extent as in Comparative Example 6, it was necessary to set the amount of the hindered amine compound introduced into the light-emitting layer to 0.01 wt. % or higher (refer to Examples 9 to 11). The reason for this is presumed to be similar to the discussion above regarding the results of Example 3. However, it was confirmed that, as described in Example 9, even when the hindered amine compound was included in the light-emitting layer at a content amount of 0.001 wt. %, the service life of the light-emitting element was longer than the lifetime of Comparative Example 1.

Note that the EQE values of Examples 10 and 11 were reduced compared to the EQE of Comparative Example 6, but for the reasons described above, there is no problem with the effect of increasing the service life of the light-emitting element.

### Example 4

A blue OLED element layer was prepared by the same method as described above with the exception that a hindered amine compound represented by the following structural formula was introduced into the light-emitting layer.

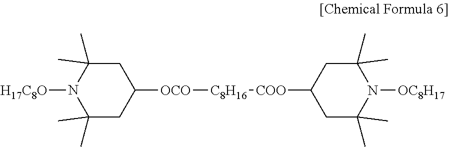

Blue OLED element layers were prepared with a content amount of the hindered amine compound in each blue OLED element layer being set to 0 (Comparative Example 7), 0.001 wt. %, 0.01 wt. %, and 0.1 wt. %, respectively. Furthermore, the service life and external quantum efficiency (EQE) of the blue OLED elements were verified using the same method as described above. The results of the present example are shown in Table 4.

TABLE 4

| | Lifetime (Time to reach 90% in | |
|---|---|---|
| Introduction (wt. %) | relation to initial luminance) (h) | EQE (%) |
| 0 (Comparative Example 7) | 35 | 11.0 |
| 0.001 (Example 12) | 43 | 11.0 |
| 0.01 (Example 13) | 58 | 10.2 |
| 0.1 (Example 14) | 57 | 8.0 |
| 0 (Comparative Example 8) | 58 | 10.7 |
| Not dipped into the stripper | | |

Table 4 shows results obtained by measuring the service life and external quantum efficiency of the blue OLED elements prepared in the present example. As shown in Table 4, as in Example 2 and Example 3 described above, it was confirmed that the service life of the blue OLED element was increased by introducing a hindered amine compound into the light-emitting layer. In order to increase the service life of the blue OLED element to the same extent as in Comparative Example 8, it was necessary to set the amount of the hindered amine compound introduced into the light-emitting layer to 0.01 wt. % or higher (refer to Examples 12 to 14). The reason for this is presumed to be similar to the discussion above regarding the results of Example 3. However, it was confirmed that, as described in Example 12, even when the hindered amine compound was included in the light-emitting layer, the service life of the light-emitting element was longer than the lifetime of Comparative Example 1.

Note that the EQE values of Examples 13 and 14 were reduced compared to the EQE of Comparative Example 8, but for the reasons described above, there is no problem with the effect of increasing the service life of the light-emitting element.

### Example 5

An OLED element was prepared based on the above-described method for manufacturing a display device. After forming a resist underlayer on a substrate having an ITO electrode, and forming a resist layer on an upper layer of the resist layer thereof, the resist underlayer and the resist layer were peeled from the substrate only at locations where green OLED elements are formed by photolithography. Note that in the exposure step, the amount of UV irradiation was 80 mJ/cm². Next, a green OLED element was formed by vapor deposition. Note that the green OLED element was configured including, on the ITO electrode, a hole injection layer, a hole transport layer, an electron blocking layer, a light-emitting layer (specifically including (2,2′-bipyridine)bis(2-phenylpyridinato)iridium (III) hexafluorophosphate and the like), a hole blocking layer, an electron transport layer, an electron injection layer, and a cathode electrode. After the OLED element was fabricated, the region at which the resist underlayer and the resist layer were formed was completely peeled from the substrate using a stripper.

Here, OLED elements having various light-emitting layers containing a nitroxy radical-type hindered amine represented by the following structural formula were prepared with the content amount of the nitroxy radical-type hindered amine in terms of a weight percentage in each light-emitting layer being 0 (Comparative Example 9), 0.0003 wt. %, 0.001 wt. %, 0.01 wt. % and 0.1 wt. % relative to the total organic material contained in the light-emitting layer.

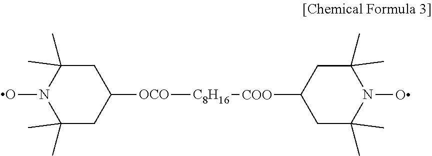

The service life of the green OLED element included in each light-emitting layer was measured at a current drive condition of 10 mA/cm² (in a 25° C. environment). Additionally, the external quantum efficiency (EQE) of the green OLED element was measured by the electric field light-emission characteristics (current voltage luminance characteristics evaluation). Furthermore, the service life and external quantum efficiency (EQE) were also evaluated for a green OLED element prepared as a Comparative Example 10 without using a stripper (specifically, without immersing (dipping) the substrate on which the green OLED element was formed, into a stripper). The results of the present example are shown in Table 5.

TABLE 5

| | Lifetime (Time to reach 90% in | |
|---|---|---|
| Introduction (wt. %) | relation to initial luminance) (h) | EQE (%) |
| 0 (Comparative Example 9) | 81 | 32.2 |
| 0.0003 (Example 15) | 112 | 32.2 |
| 0.001 (Example 16) | 115 | 31.7 |
| 0.01 (Example 17) | 126 | 30.0 |
| 0.1 (Example 18) | 130 | 28.4 |
| 0 (Comparative Example 10) | 133 | 31.7 |
| Not dipped into the stripper | | |

Table 5 shows results obtained by measuring the service life and external quantum efficiency of the green OLED elements prepared in the present example.

The service life of the green OLED element was increased when a nitroxy radical-type hindered amine was introduced into the light-emitting layer at the content amounts indicated in Table 5 for Examples 15 to 18. It was confirmed that this service life was a numerical value substantially close to the service life of the green OLED element (Comparative Example 10) prepared without using a stripper.

Note that the EQE values of Examples 16,17 and 18 were reduced compared to the EQE of Comparative Example 9, but for the reasons described above, there is no problem with the effect of increasing the service life of the light-emitting element.

### Example 6

An OLED element was prepared based on the above-described method for manufacturing a display device. After forming a resist underlayer on a substrate having an ITO electrode, and forming a resist layer on an upper layer of the resist layer thereof, the resist underlayer and the resist layer were peeled from the substrate only at locations where red OLED elements are formed by photolithography. Note that in the exposure step, the amount of UV irradiation was 80 mJ/cm². Next, a red OLED element was formed by vapor deposition. Note that the red OLED element was configured including, on the ITO electrode, a hole injection layer, a hole transport layer, an electron blocking layer, a light-emitting layer (specifically including tris(8-quinolinolato)aluminum, tris[1-phenylisoquinoline-C²,N]iridium, and the like), a hole blocking layer, an electron transport layer, an electron injection layer, and a cathode electrode. After the OLED element was fabricated, the region at which the resist underlayer and the resist layer were formed was completely peeled from the substrate using a stripper.

Here, OLED elements having various light-emitting layers containing a nitroxy radical-type hindered amine represented by the following structural formula were prepared with the content amount of the nitroxy radical-type hindered amine in terms of a weight percentage in each light-emitting layer being 0 (Comparative Example 11), 0.0003 wt. %, 0.001 wt. %, 0.01 wt. % and 0.1 wt. % relative to the total organic material contained in the light-emitting layer.

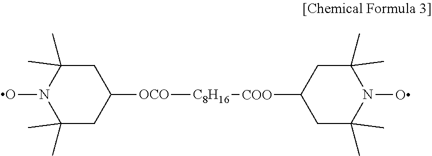

The service life of the red OLED element included in each light-emitting layer was measured at a current drive condition of 10 mA/cm² (in a 25° C. environment). Additionally, the external quantum efficiency (EQE) of the red OLED element was measured by the electric field light-emission characteristics (current voltage luminance characteristics evaluation). Furthermore, the service life and external quantum efficiency (EQE) were also evaluated for a red OLED element prepared as a Comparative Example 12 without using a stripper (specifically, without immersing (dipping) the substrate on which the red OLED element was formed, into a stripper). The results of the present example are shown in Table 6.

TABLE 6

| | Lifetime (Time to reach 90% in | |
|---|---|---|
| Introduction (wt. %) | relation to initial luminance) (h) | EQE (%) |
| 0 (Comparative Example 11) | 520 | 34.0 |
| 0.0003 (Example 19) | 574 | 34.0 |
| 0.001 (Example 20) | 573 | 33.3 |
| 0.01 (Example 21) | 589 | 33.1 |
| 0.1 (Example 22) | 585 | 31.5 |
| 0 (Comparative Example 12) | 590 | 33.8 |
| Not dipped into the stripper | | |

Table 6 shows results obtained by measuring the service life and external quantum efficiency of the red OLED elements prepared in the present example.

The service life of the red OLED element was increased when a nitroxy radical-type hindered amine was introduced into the light-emitting layer at the content amounts indicated in Table 6 for Examples 19 to 22. It was confirmed that this service life was a numerical value substantially close to the service life of the red OLED element (Comparative Example 12) prepared without using a stripper.

Note that the EQE values of Examples 20, 21 and 22 were reduced compared to the EQE of Comparative Example 11, but for the reasons described above, there is no problem with the effect of increasing the service life of the light-emitting element.

The above results demonstrated that the service life of an OLED element can be lengthened by including a hindered amine compound and a derivative of a hindered amine compound in the light-emitting layer. In addition, it was verified that compared to the inclusion of a hindered amine compound in the light-emitting layer, when, among hindered amine compounds, a nitroxy radical-type hindered amine in particular is included in the light-emitting layer, a significant effect of increasing the service life of the OLED element is demonstrated.

### Supplement

A display device according to one aspect of the present invention is provided with: a display region that includes a light-emitting element layer containing a plurality of light-emitting elements, a TFT layer provided below the light-emitting element layer and configured to drive the light-emitting elements, and a sealing layer covering the light-emitting element layer; and a frame region surrounding the display region, wherein the light-emitting element layer is provided with a plurality of light-emitting layers, and each of the light-emitting layers contains a hindered amine compound and/or a derivative of a hindered amine compound.

According to the above configuration, quenching of a luminescent body caused by the conversion of an oxide into a radical can be suppressed by introducing a hindered amine compound into the light-emitting layer without using a fine metal mask. Therefore, it is possible to produce a display device provided with an OLED having a long service life.

With respect to the above-mentioned display device, the plurality of light-emitting layers includes: a first light-emitting layer containing a blue light-emitting element; a second light-emitting layer including a green light-emitting element; and a third light-emitting layer including a red light-emitting element; and the content amount of the hindered amine compound or the derivative of the hindered amine compound included in each of the first light-emitting layer, the second light-emitting layer, and the third light-emitting layer may be respectively different.

According to the above configuration, even in each light-emitting layer, a reduction in the service life of a light-emitting element can be suppressed by increasing the radical scavenging effect with respect to a light-emitting element for which there is a concern that the service life of the light-emitting element could be relatively reduced.

With respect to the above-mentioned display device, the content amount of the hindered amine compound or the derivative of the hindered amine compound included in each of the first light-emitting layer, the second light-emitting layer, and the third light-emitting layer is reduced in the order of the first light-emitting layer, the second light-emitting layer, and the third light-emitting layer.

According to the above configuration, even in each light-emitting layer, a reduction in the service life of a light-emitting element can be suppressed by increasing the radical scavenging effect with respect to a light-emitting element for which there is a concern that the service life of the light-emitting element could be relatively reduced. Note that examples of light-emitting elements for which there is a concern regarding a relative reduction in the service life of the light-emitting element include blue light-emitting elements or green light-emitting elements. Blue light-emitting elements and green light-emitting elements require a large amount of energy for light emission (that is, a large drive current for the light-emitting element) in comparison to red light-emitting elements. Since a large amount of energy is required, degradation (oxidation or the like) of the organic material is also likely to occur.

With respect to the above-mentioned display device, the first light-emitting layer may include, as luminescent materials, an anthracene-based compound and a derivative of an anthracene-based compound.

According to the above-described configuration, a display device that includes a light-emitting element having high efficiency and more vivid blue light emission is obtained.

With respect to the above-mentioned display device, the second light-emitting layer may include, as luminescent materials, a P-type host material and an N-type host material.

According to the above-described configuration, a light-emitting layer that includes a luminescent material that facilitates a balance between efficiency with respect to electroluminescence and service life of an element can be realized.

With respect to the above-mentioned display device, the third light-emitting layer may include, as a luminescent material, a P-type host material and/or an N-type host material.

According to the configuration described above, the service life and efficiency of the third light-emitting layer can be easily increased.

With respect to the above-mentioned display device, the hindered amine compound may be any of the compounds represented by the following structural formulas.

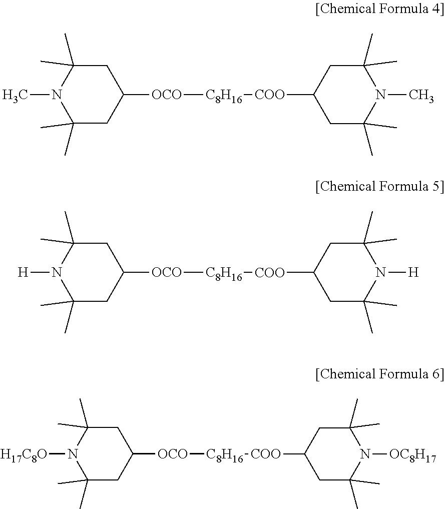

According to the above configuration, a display device provided with an OLED with a long service life can be fabricated.

With respect to the above-mentioned display device, the content amount of the hindered amine compound contained in the first light-emitting layer may be from 0.001 wt. % to 0.1 wt. %.

The configuration described above contributes to improving the efficiency of the OLED, and exhibiting an effect of suppressing a reduction in service life.

With respect to the above-mentioned display device, the derivative of the hindered amine compound may be a nitroxy radical-type hindered amine containing a nitroxy radical.

According to the configuration described above, through the use of a nitroxy radical-type hindered amine, the radical scavenging efficiency is further improved, and an OLED with a longer service life can be obtained.

The nitroxy radical-type hindered amine may be a compound having a structure represented by the following general formula.

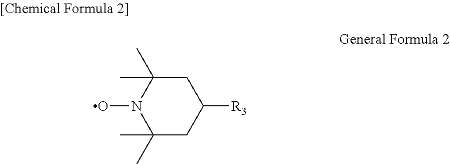

In the general formula, R₃ is any organic group.

According to the above configuration, an OLED with a long service life can be obtained by including a compound having a structure configured to realize a higher radical scavenging efficiency.

With respect to the above-mentioned display device, the nitroxy radical-type hindered amine may be a substance represented by the following structural formula.

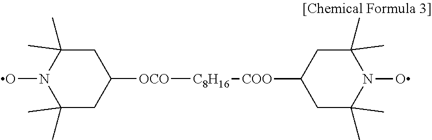

According to the above configuration, an OLED with a long service life is obtained by including a compound configured to achieve higher radical scavenging efficiency.

With respect to the above-mentioned display device, the content amount of the nitroxy radical-type hindered amine contained in the first light-emitting layer may be from 0.0003 wt. % to 0.01 wt. %.

The configuration described above contributes to improving the efficiency of the OLED, and exhibiting an effect of suppressing a reduction in service life.

A method of manufacturing a display device according to an aspect of the present invention is a method of manufacturing a display device by forming, on a substrate, a light-emitting element layer that is patterned, the method including the steps of: forming a mask pattern on the substrate using a photoresist; vapor depositing a light-emitting element material containing a hindered amine compound and/or a derivative of a hindered amine compound onto the substrate using an open mask; and removing the mask pattern from the substrate.

According to the above configuration, quenching of a luminescent body caused by the conversion of an oxide into a radical can be suppressed by introducing a hindered amine compound into the light-emitting layer without using a fine metal mask. Therefore, it is possible to produce a display device provided with an OLED having a long service life.

With respect to the above-mentioned method of manufacturing a display device, the light-emitting element layer includes a first light-emitting layer containing a blue light-emitting element, a second light-emitting layer containing a green light-emitting element, and a third light-emitting layer containing a red light-emitting element, each of the light-emitting layers is formed in order and contains a nitroxy radical-type hindered amine, and a content amount of the nitroxy radical-type hindered amine contained in each of the light-emitting layers is reduced in accordance with the above-mentioned order.

According to the configuration described above, in the case where the above-mentioned steps are repeated, even when the first light-emitting layer and the second light-emitting layer formed ahead of the third light-emitting layer contact the solvent multiple times, the high radical scavenging effect can be maintained by the nitroxy radical-type hindered amine contained in the light-emitting layers.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in the embodiments.

### REFERENCE SIGNS LIST

1 Display device
5 Light-emitting element layer
4 TFT layer
6 Sealing layer

1. A display device comprising:
a display region including a light-emitting element layer containing a plurality of light-emitting elements, a TFT layer provided below the light-emitting element layer and configured to drive the plurality of light-emitting elements, and a sealing layer covering the light-emitting element layer; and
a frame region surrounding the display region,
wherein the light-emitting element layer is provided with a plurality of light-emitting layers, and
each of the plurality of light-emitting layers contains a hindered amine compound and/or a derivative of a hindered amine compound.

2. The display device according to claim 1,
wherein the plurality of light-emitting layers includes:
a first light-emitting layer containing a blue light-emitting element;
a second light-emitting layer containing a green light-emitting element; and
a third light-emitting layer containing a red light-emitting element, and
a content amount of the hindered amine compound or the derivative of the hindered amine compound included in each of the first light-emitting layer, the second light-emitting layer, and the third light-emitting layer differs respectively.

3. The display device according to claim 2,
wherein the content amount of the hindered amine compound or the derivative of the hindered amine compound included in each of the first light-emitting layer, the second light-emitting layer, and the third light-emitting layer is reduced in the order of the first light-emitting layer, the second light-emitting layer, and the third light-emitting layer.

4. The display device according to claim 2,
wherein the first light-emitting layer comprises, as luminescent materials, an anthracene-based compound and a derivative of an anthracene-based compound.

5. The display device according to claim 2,
wherein the second light-emitting layer comprises a P-type host material and an N-type host material as luminescent materials.

6. The display device according to claim 2,
wherein the third light-emitting layer comprises a P-type host material and/or an N-type host material as a luminescent material.

7. The display device according to claim 2,
wherein the hindered amine compound is any compound represented by the following structural formulas.

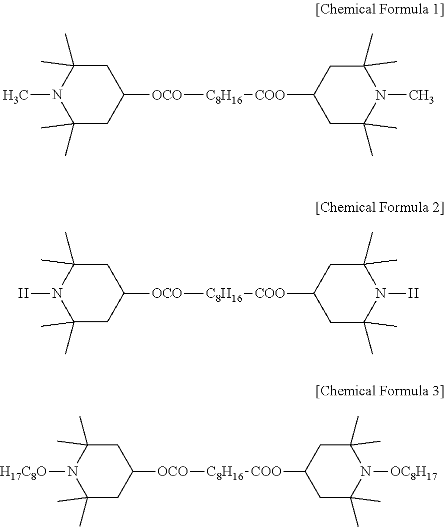

8. The display device according to claim 7,
wherein the content amount of the hindered amine compound contained in the first light-emitting layer is from 0.001 wt. % to 0.1 wt. %.

9. The display device according to claim 2,
wherein the derivative of the hindered amine compound is a nitroxy radical-type hindered amine containing a nitroxy radical.

10. The display device according to claim 9,
wherein the nitroxy radical-type hindered amine is a compound having a structure represented by the following general formula 1: 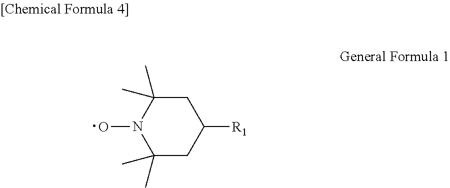
(wherein, R₁ is any organic group).

11. The display device according to claim 9,
wherein the nitroxy radical-type hindered amine is represented by the following structural formula.

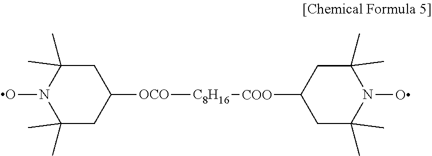

12. The display device according to claim 10,
wherein a content amount of the nitroxy radical-type hindered amine contained in the first light-emitting layer is from 0.0003 wt. % to 0.01 wt. %.

13. A method of manufacturing a display device by forming, on a substrate, a light-emitting element layer that is patterned, the method comprising the steps of:
forming a mask pattern on the substrate using a photoresist;
vapor depositing a light-emitting element material containing a hindered amine compound and/or a derivative of a hindered amine compound onto the substrate using an open mask; and
removing the mask pattern from the substrate.

14. The method of manufacturing a display device according to claim 13,
wherein the light-emitting element layer includes a first light-emitting layer containing a blue light-emitting element, a second light-emitting layer containing a green light-emitting element, and a third light-emitting layer containing a red light-emitting element,
each of the light-emitting layers is formed in order and contains a nitroxy radical-type hindered amine, and
a content amount of the nitroxy radical-type hindered amine contained in each of the light-emitting layers is reduced in accordance with the above-mentioned order.
